(19) United States
(12) Patent Application Publication
(10) Pub. No.: US 2026/0074694 A1
(43) Pub. Date: Mar. 12, 2026

(54) LEVEL SHIFTING CIRCUIT

(71) Applicant: Socionext Inc., Kanagawa (JP)

(72) Inventor: Kyota SHIMIZU, Yokohama-shi (JP)

(21) Appl. No.: 19/387,882

(22) Filed: Nov. 13, 2025

Related U.S. Application Data
(63) Continuation of application No. PCT/JP2023/018052, filed on May 15, 2023.

(51) Int. Cl. H03K 19/00; H03K 19/017

(52) U.S. Cl. CPC H03K 19/0013; H03K 19/017

(57) ABSTRACT

A level shifting circuit includes first to sixth p-type transistors, first and second n-type transistors, and first and second resistors. The first p-type transistor and the first n-type transistor are provided between an input node and an output node. The second p-type transistor is provided between a third power supply and the output node. The third p-type transistor is provided between a first power supply and the output node. The first resistor is provided between a third node and the output node. The fourth p-type transistor and the second n-type transistor are provided between an inverted input node and an inverted output node. The fifth p-type transistor is provided between the third power supply and the inverted output node. The sixth p-type transistor is provided between the first power supply and the inverted output node. The second resistor is provided between a sixth node and the inverted output node.

### CROSS-REFERENCE TO RELATED APPLICATIONS

This is a continuation of International Application No. PCT/JP2023/018052 filed on May 15, 2023. The entire disclosure of this application is incorporated by reference herein.

### BACKGROUND

The present disclosure relates to a level shifting circuit that converts the voltage of a signal to a required level when the signal is propagated between circuits to which different power supply voltages are supplied.

A level shifting circuit is provided in an interface part in which a signal is transmitted from a circuit operating at a relatively low voltage inside an LSI to a circuit operating at a relatively high voltage outside the LSI, for example, and used at the conversion of the voltage of the signal.

In recent years, with the miniaturization of transistors, the transistor-tolerable voltage stress (withstanding voltage) is increasingly decreasing. Given this backdrop, a level shifting circuit that performs voltage conversion within a predetermined withstanding voltage range has been conventionally disclosed.

A level shifting circuit disclosed in United States Patent No. 7,151,391 is configured to step up a Low-level voltage in addition to stepping up a High-level voltage. In this way, by decreasing the voltage between the Low and High levels, the voltage applied across the terminals (e.g., gate-source and source-drain) of a transistor decreases, whereby the voltage stress to the transistor is lightened.

In the configuration in FIG. 1 of the cited patent document, however, the following problem arises: the operation of the level shifting circuit fails to respond to reduction in operating voltages along with requests for lower power consumption and/or speedup of circuit operation along with requests for higher functionality.

An objective of the present disclosure is solving the above-described problem.

### SUMMARY

According to the first mode of the disclosure, a level shifting circuit includes: an input node receiving an input signal that makes a transition between a first power supply and a second power supply lower in potential than the first power supply; a first n-type transistor provided between the input node and an output node and having a gate connected to the first power supply; a first p-type transistor provided in parallel with the first n-type transistor between the input node and the output node and having a gate connected to a first node; a first resistor provided between the first node and the output node; a second p-type transistor provided between a third power supply higher in potential than the first power supply and the output node and having a gate connected to an inverted output node; a third p-type transistor provided between the first power supply and the output node and having a gate connected to the output node via a second node; an inverted input node receiving an inverted input signal inverted from the input signal; a second n-type transistor provided between the inverted input node and the inverted output node and having a gate connected to the first power supply; a fourth p-type transistor provided in parallel with the second n-type transistor between the inverted input node and the inverted output node and having a gate connected to a third node; a second resistor provided between the third node and the inverted output node; a fifth p-type transistor provided between the third power supply and the inverted output node and having a gate connected to the output node; and a sixth p-type transistor provided between the first power supply and the inverted output node and having a gate connected to the inverted output node via a fourth node.

In the level shifting circuit of this mode, in the operation in which the input signal changes from Low level to High level, since the fourth p-type transistor turns ON together with the turning-ON of the second n-type transistor, the falling speed at the inverted output node increases. This hastens the turning-ON of the second p-type transistor, thereby increasing the rising speed of the output signal. Also, since the gate-source voltage (Vgs) at the ON time of the second p-type transistor is higher than in the cited patent document, the switching operation speeds up, thereby increasing the rising speed of the output signal. At this time, since the first p-type transistor is OFF, the rise of the output signal is not hindered.

In the level shifting circuit of this mode, the circuit connected to the input node and the circuit connected to the inverted input node are configured symmetrically. Therefore, in the case where the input signal changes from High level to Low level, also, the circuit operates similarly, increasing the falling speed of the output signal.

Moreover, the level shifting circuit of this mode is configured using two power supplies, i.e., the first power supply and the third power supply, not using a bias voltage (corresponding to VBIAS in the cited patent document). That is, no circuit for generating a bias voltage is necessary.

According to the present disclosure, in a level shifting circuit, reduction in operating voltages and/or speedup of circuit operation are achieved.

### BRIEF DESCRIPTION OF THE DRAWINGS

FIG. 1 is a circuit diagram showing an example of the configuration of a level shifting circuit according to the first embodiment.

FIG. 2 is a view showing an example of voltage waveforms at nodes in the level shifting circuit.

FIG. 3 is a circuit diagram showing an example of the configuration of a level shifting circuit according to the second embodiment.

FIG. 4 is a circuit diagram showing an example of the configuration of a level shifting circuit according to the third embodiment.

FIG. 5 is a circuit diagram showing an example of the configuration of a level shifting circuit according to the fourth embodiment.

FIG. 6 is a circuit diagram showing an alteration of the level shifting circuit according to the fourth embodiment.

FIG. 7 is a circuit diagram showing an example of the configuration of a level shifting circuit according to the fifth embodiment.

FIG. 8 is a circuit diagram showing an example of the configuration of a selector circuit.

FIG. 9 is a circuit diagram showing an alteration of the level shifting circuit according to the fifth embodiment.

### DETAILED DESCRIPTION

Embodiments of the present disclosure will be described hereinafter. Note that specific numerical values and the like indicated in the following embodiments are mere examples for facilitating the understanding of the disclosure and by no means intended to limit the scope of the disclosure. Note that a node of a circuit and a signal passing through the node may be described under the same reference character. Also, a power supply and a power supply voltage of the power supply may be described under the same reference character.

### First Embodiment

A level shifting circuit 1, constituted by two power supplies, i.e., a first power supply VDD and a third power supply VDDIO, is a circuit that steps up a High-level voltage from VDD to VDDIO and also steps up a Low-level voltage from VSS to VDD. The third power supply VDDIO is higher in voltage than the first power supply VDD. Note that, in the following description, Low level may be simply expressed as ‘L’ and High level as ‘H’.

The level shifting circuit 1 receives an input signal IN that makes transitions between the first power supply VDD and the ground VSS (corresponding to the second power supply) from an input terminal IN (input node in), and outputs an output signal OUT that makes transitions between the third power supply VDDIO and the first power supply VDD from an output terminal OUT (output node out). In other words, the input signal IN is a signal having an amplitude of VDD, and the output signal OUT is a signal having an amplitude of (VDDIO – VDD).

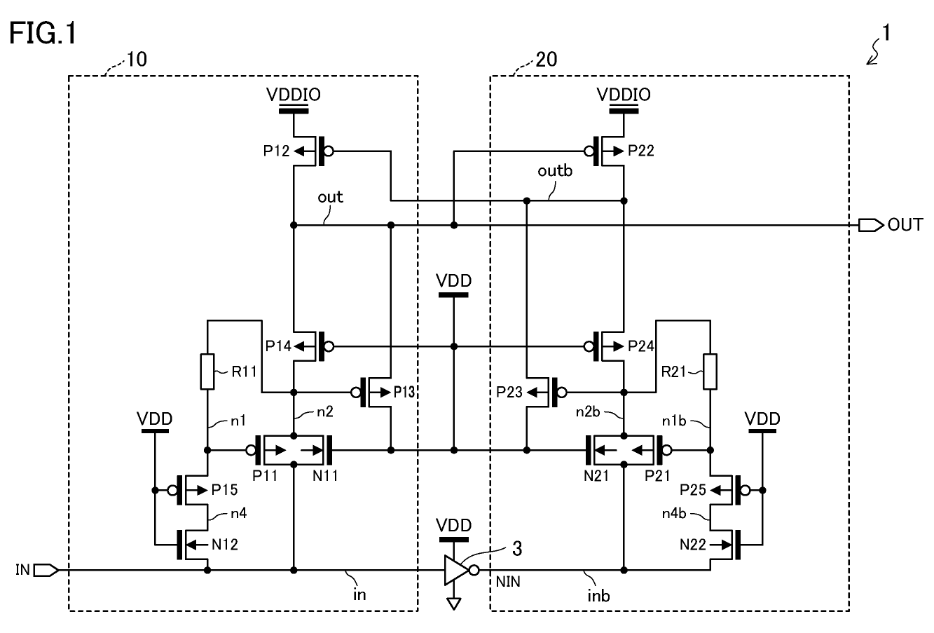

FIG. 1 shows an example of the circuit diagram of the level shifting circuit 1 according to the first embodiment.

The level shifting circuit 1 includes a first circuit 10, a second circuit 20, and an inverter 3 that inverts the input signal IN to generate an inverted input signal NIN.

The inverter 3 receives the input signal IN as an input and outputs the inverted input signal NIN to the second circuit 20. The power terminal of the inverter 3 is connected to the first power supply VDD, and the ground terminal thereof is connected to the ground VSS. Note that the inverter 3 may be omitted from FIG. 1. For example, a circuit (not shown) preceding the level shifting circuit 1 may generate the input signal IN and the inverted input signal NIN, and output these signals to the level shifting circuit 1. This also applies to the other figures(other embodiments).

The first circuit 10 and the second circuit 20 are symmetric to each other in configuration. These circuits will be described individually with reference to the drawing.

### First Circuit

The first circuit 10 includes n-type transistors N11 and N12, p-type transistors P11 to P15, and a resistor R11. The n-type transistor N11 (corresponding to the first n-type transistor) and the p-type transistor P11 (corresponding to the first p-type transistor) are provided between the input node in and the output node out.

The n-type transistor N11 and the p-type transistor P11 share the source and the drain: specifically, the source of the n-type transistor N11 and the drain of the p-type transistor P11 are shared and connected to the input node in, and the drain of the n-type transistor N11 and the source of the p-type transistor P11 are shared and connected to a node n2 (corresponding to the second node). The gate of the n-type transistor N11 is connected to the first power supply VDD, and the gate of the p-type transistor P11 is connected to a node n1 (corresponding to the first node).

Note that, in the present disclosure, the term “connection” is a concept widely covering any electrical connection between components, including, not only the case that components are connected directly, but also the case that components are electrically connected indirectly via a passive element, etc. For example, the wording “the node n2 is connected to the output node out” includes a configuration in which the node n2 is connected to the output node out via the p-type transistor P14, as shown in FIG. 1.

The p-type transistor P12 (corresponding to the second p-type transistor) is provided between the third power supply VDDIO and the output node out, and has a gate connected to an inverted output node outb.

The p-type transistor P13 (corresponding to the third p-type transistor) is provided between the first power supply VDD and the output node out, and has a gate connected to the node n2.

The p-type transistor P14 (corresponding to the seventh p-type transistor) is provided between the node n2 and the output node out, and has a gate connected to the first power supply VDD. Note that the p-type transistor P14 may be omitted, but by providing the p-type transistor P14, the electrical connection between the first power supply VDD and the input node in via the p-type transistor P13 and the n-type transistor N11 is shut off.

The n-type transistor N12, the p-type transistor P15, and the resistor R11 are serially connected between the input node in and the node n2.

The n-type transistor N12 (corresponding to the third n-type transistor) is provided between the input node in and a node n4 (corresponding to the fifth node), and has a gate connected to the first power supply VDD. The p-type transistor P15 (corresponding to the eighth p-type transistor) is provided between the node n4 and the node n1, and has a gate connected to the first power supply VDD. Note that the n-type transistor N12 and the p-type transistor P15 may be omitted, but by providing these transistors, voltage drop at the node n1 is sped up.

The resistor R11 (corresponding to the first resistor) is provided between the node n1 and the node n2. The resistor R11 is connected to the output node out via the node n2 and the p-type transistor P14. In other words, the resistor R11 is provided between the node n1 and the output node out. As the resistor R11, any element or the like functioning as a resistor can be used without any specific limitation. For example, as the resistor R11, the ON-resistance of an always-ON transistor and a diode may be used in addition to a resistor element. This also applies to a resistor R21 to be described later.

### Second Circuit

The second circuit 20, configured to be symmetric to the first circuit 10 as described above, includes n-type transistors N21 and N22, p-type transistors P21 to P25, and a resistor R21.

The n-type transistor N21 (corresponding to the second n-type transistor) and the p-type transistor P21 (corresponding to the fourth p-type transistor) are provided between an inverted input node inb and the inverted output node outb.

The n-type transistor N21 and the p-type transistor P21 share the drain and the source: specifically, the source of the n-type transistor N21 and the drain of the p-type transistor P21 are shared and connected to the inverted input node inb, and the drain of the n-type transistor N21 and the source of the p-type transistor P21 are shared and connected to a node n2b (corresponding to the fourth node). The gate of the n-type transistor N21 is connected to the first power supply VDD, and the gate of the p-type transistor P21 is connected to a node n1b (corresponding to the third node).

The p-type transistor P22 (corresponding to the fifth p-type transistor) is provided between the third power supply VDDIO and the inverted output node outb, and has a gate connected to the output node out.

The p-type transistor P23 (corresponding to the sixth p-type transistor) is provided between the first power supply VDD and the inverted output node outb, and has a gate connected to the node n2b.

The p-type transistor P24 (corresponding to the ninth p-type transistor) is provided between the node n2b and the inverted output node outb, and has a gate connected to the first power supply VDD. Note that the p-type transistor P24 may be omitted, but by providing the p-type transistor P24, the electrical connection between the first power supply VDD and the inverted input node inb via the p-type transistor P23 and the n-type transistor N21 is shut off.

The n-type transistor N22, the p-type transistor P25, and the resistor R21 are serially connected between the inverted input node inb and the node n2b.

The n-type transistor N22 (corresponding to the fourth n-type transistor) is provided between the inverted input node inb and a node n4b (corresponding to the sixth node), and has a gate connected to the first power supply VDD. The p-type transistor P25 (corresponding to the tenth p-type transistor) is provided between the node n4b and the node n1b, and has a gate connected to the first power supply VDD. Note that the n-type transistor N22 and the p-type transistor P25 may be omitted, but by providing these transistors, the voltage drop at the node n1b is sped up.

The resistor R21 (corresponding to the second resistor) is provided between the node n1b and the node n2b. The resistor R21 is connected to the inverted output node outb via the node n2b and the p-type transistor P24. In other words, the resistor R21 is provided between the node n1b and the inverted output node outb.

### Operation of Level Shifting Circuit

Next, the operation of the level shifting circuit 1 according to this embodiment will be described.

### Operation Example (1-1)

The operation at the time when ‘L’ is input as the input signal IN and ‘L’ is output as the output signal OUT, i.e., at the time when the voltage of the input signal is VSS and the voltage of the output signal is VDD will be described. In the following description, the gate-source voltage Vgs of a transistor is simply described as “Vgs”.

In the first circuit 10, since the input signal IN is ‘L’, the n-type transistors N11 and N12 are ON, and the nodes n1, n2, and n4 become ‘L’ (voltage VSS), whereby the p-type transistor P13 turns ON. With this, the voltage of the output node out becomes VDD. That is, ‘L’ (voltage VDD) is output from the output terminal OUT.

In the second circuit 20, since the voltage of the output node out is VDD, the p-type transistors P22, P24, and P25 are ON. With this, the voltages of the nodes n1b, n2b, and n4b and the inverted output node outb become VDDIO. Also, since the inverted input signal NIN is ‘H’, the voltage of the inverted input node inb is VDD.

### Operation Example (1-2)

The operation at the time when ‘H’ is input as the input signal IN and ‘H’ is output as the output signal OUT, i.e., at the time when the voltage of the input signal is VDD and the voltage of the output signal is VDDIO will be described.

In the second circuit 20, since the inverted input signal NIN is ‘L’, the n-type transistors N21 and N22 are ON, and the nodes n1b, n2b, and n4b become ‘L’ (voltage VSS), whereby the p-type transistor P23 turns ON. With this, the voltage of the inverted output node outb becomes VDD.

In the first circuit 10, since the voltage of the inverted output node outb is VDD, the p-type transistors P12, P14, and P15 are ON. With this, the voltages of the nodes n1, n2, and n4 and the output node out become VDDIO. That is, ‘H’ (VDDIO) is output from the output terminal OUT.

### Operation Example (1-3)

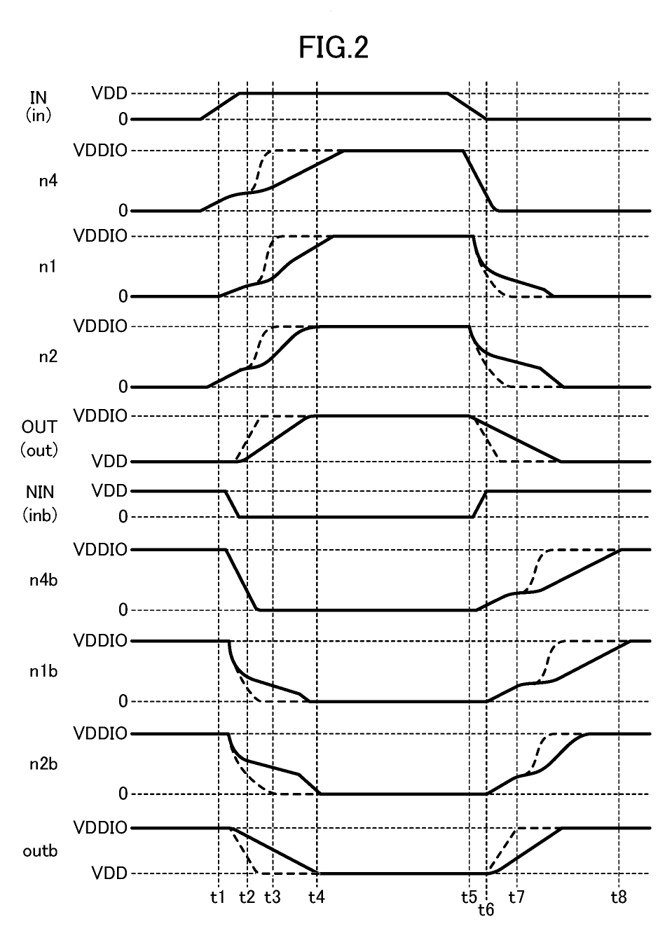

The operation at the time when the input signal IN changes from ‘L’ to ‘H’ and the output signal OUT changes from ‘L’ to ‘H’ will be described with reference to the solid-line waveforms in FIG. 2. At this time, the voltage of the input signal changes from VSS to VDD and the voltage of the output signal changes from VDD to VDDIO.

In the first circuit 10, when the input signal IN starts to rise from ‘L’ toward ‘H’, the voltages of the nodes n1, n2, and n4 start to rise with the rise of the input signal IN (see time t1). With this, the Vgs of the n-type transistors N11 and N12 (Vgs = VDD – VIN) starts to decrease, where VIN is the voltage of the input signal IN. Since the n-type transistors N11 and N12 turn OFF when Vgs becomes less than the threshold, the rises of the voltages of the nodes n1, n2, and n4 become sluggish temporarily (see time t2 to time t3).

In the second circuit 20, when the inverted input signal NIN starts to fall from ‘H’ toward ‘L’, the voltages of the nodes n1b, n2b, and n4b and the inverted output node outb start to fall with the fall of the inverted input signal NIN (see time t2). The p-type transistor P22 turns OFF when Vgs becomes less than the threshold.

In the first circuit 10, the p-type transistor P12 turns ON when Vgs exceeds the threshold with the fall of the voltage of the inverted output node outb. With this, the output signal OUT starts to rise from ‘L’ to ‘H’ (see time t1 to time t2). The p-type transistor P14 turns ON when Vgs exceeds the threshold with the rise of the output signal OUT. With this, the once-sluggish rises of the voltages of the nodes n1 and n2 are sped up (see time t3). The p-type transistor P13 turns OFF when Vgs becomes less than the threshold with the rise of the voltage of the node n2. This shuts off the conduction between the third power supply VDDIO and the first power supply VDD via the p-type transistors P12 and P13, and therefore the voltage of the output signal OUT rises up to VDDIO. That is, the output signal OUT becomes ‘H’.

At this time, in the first circuit 10, since the voltage of the node n1 rises together with the voltage of the node n4, the p-type transistor P11 turns OFF with its Vgs becoming less than the threshold. This shuts off the conduction between VDDIO and the input node in, and therefore the voltage rise of the output signal OUT is prevented from being hindered and delayed (see time t3 to time t4).

In the second circuit 20, as described above, the voltages of the nodes n1b and n4b and the inverted output node outb fall, and the p-type transistors P24 and P25 turn OFF when Vgs becomes less than the threshold. On the other hand, since the n-type transistor N21 is ON, the voltages of the nodes n1b and n2b fall down to VSS (see time t4). The p-type transistor P23 turns ON when Vgs exceeds the threshold with the fall of the voltage of the node n2b. With this, the voltage of the inverted output node outb falls down to VDD (see time t4).

At this time, since the resistor R21 is interposed between the node n2b and the node n1b, a voltage drop occurs at both ends of the resistor R21 due to a discharge current from the node n2b to the inverted input node inb (VSS). In view of this, the resistance value of the resistor R21 is set at a value with which the potential difference between the node n1b and the node n2b exceeds the threshold of the Vgs of the p-type transistor P21. By this setting, the p-type transistor P21 turns ON, whereby the n-type transistor N21 and the p-type transistor P21 are ON in parallel. With this, the voltage drop at the node n2b is sped up, and, this can serve, together with the turning-ON of the p-type transistor P23, to speed up the fall of the inverted output node outb (see time t2 to time t4).

Note that, as described above, since the p-type transistors P24 and P25 are OFF with the fall of the voltage of the inverted output node outb, the conduction between the first power supply VDD and the inverted input node inb via the p-type transistor P23 is shut off.

### Operation Example (1-4)

The operation at the time when the input signal IN changes from ‘H’ to ‘L’ and the output signal OUT changes from ‘H’ to ‘L’ will be described. At this time, the voltage of the input signal changes from VDD to VSS and the voltage of the output signal changes from VDDIO to VDD.

As described above, the first circuit 10 and the second circuit 20 are symmetric to each other in configuration. When the input signal IN changes from ‘H’ to ‘L’, the inverted input signal NIN changes from ‘L’ to ‘H’. Therefore, in this operation example, the first circuit 10 and the second circuit 20 perform reciprocal operations in comparison with Operation Example (1-3). That is, in the voltage waveforms in FIG. 2, although there is a lag in input timing between the input node in and the inverted input node inb, the operation is performed as if the input node in is replaced with the inverted input node inb, the node n4 with the node n4b, the node n1 with the node n1b, the node n2 with the node n2b, and the output node out with the inverted output node outb.

### Effects of First Embodiment

As described above, according to this embodiment, high-speed operation of the level shifting circuit 1 can be achieved.

Specifically, in Operation Example (1-3), since the p-type transistor P21 turns ON in parallel when the n-type transistor N21 is ON, the falling speed at the inverted output node outb increases, and therefore the turning-ON of the p-type transistor P12 is hastened. This increases the rising speed of the output signal OUT. Moreover, since the Vgs (VDDIO – VDD) of the p-type transistor P12 at its ON time is higher than the Vgs (VDDIO – VBIAS) of the transistor in the cited patent document, the switching operation is faster. This further increases the rising speed of the output signal OUT. Also, at the rise of the output signal OUT, since the p-type transistor P11 is OFF, there is no conduction between VDDIO and the input node in (voltage VDD), and therefore the rise of the output signal OUT is not hindered.

Similarly, in Operation Example (1-4), since the p-type transistor P11 turns ON in parallel when the n-type transistor N11 is ON, the falling speed at the node n2 increases, and therefore the turning-ON of the p-type transistor P13 is hastened. This increases the falling speed of the output signal OUT. Moreover, since the Vgs (VDDIO – VDD) of the p-type transistor P22 at the ON time is higher than the Vgs (VDDIO – VBIAS) of the transistor in the cited patent document, the switching operation is faster. This further increases the rising speed of the voltage of the inverted output node outb. Also, at the rise of the inverted output signal outb, since the p-type transistor P21 is OFF, there is no conduction between VDDIO and the inverted input node inb (voltage VDD), and therefore the rise at the inverted output node outb is not hindered.

Also, the level shifting circuit 1 of this embodiment is constituted by two power supplies, i.e., the first power supply VDD and the third power supply VDDIO. That is, since no bias voltage (VBIAS) is used unlike the cited patent document, neither designing of a bias generation circuit for generating a bias volage inside an LSI nor mounting of the circuit in the LSI is necessary.

### Second Embodiment

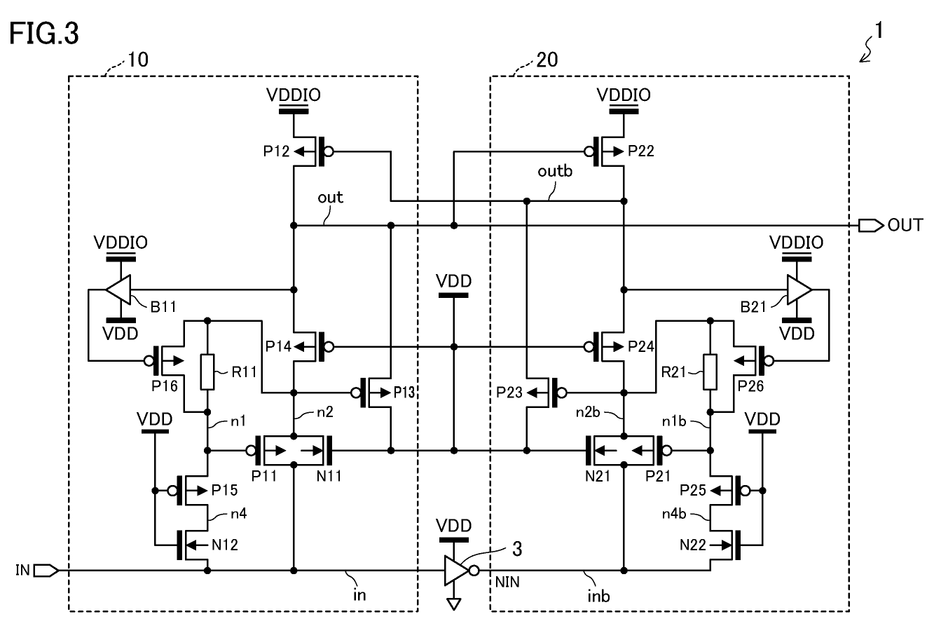

FIG. 3 shows an example of the circuit diagram of a level shifting circuit 1 according to the second embodiment. In FIG. 3, components corresponding to those in FIG. 1 are denoted by the same reference characters. The following description will be made centering on differences from the first embodiment. Note that elements (e.g., transistors and inverters) denoted by the same reference characters in FIGS. 1 and 3 are not intended to be the same in various design parameters, process parameters, and the like. That is, configurations in which elements denoted by the same reference characters in FIGS. 1 and 3 have parameters different from each other also fall within the technical scope of the present disclosure. This also applies to the relationships between other drawings.

The level shifting circuit 1 of this embodiment is configured to further speed up the rise of the output signal OUT from ‘L’ to ‘H’ in comparison with the first embodiment.

In the configuration of the first embodiment, at the time of rising at the nodes n1 and n2, there is a time period when the Vgs of the p-type transistor P11 exceeds the threshold due to the voltage drop at both ends of the resistor R11 whereby the p-type transistor P11 turns ON. When the p-type transistor P11 turns ON, the node n2 and the input node in are brought into conduction. During this time period, therefore, the voltage rise at the node n2 is mild, whereby the turning-OFF of the p-type transistor P13 may be delayed. This delay may cause a time period when the third power supply VDDIO and the first power supply VDD are be brought into conduction via the p-type transistors P12 and P13, and result in affecting the improvement in the rising speed of the output signal OUT.

In view of the above, in this embodiment, from the standpoint of speeding up the rise of the output signal OUT, short circuits for the resistors R11 and R21 are provided in addition to the configuration of the first embodiment.

Specifically, in this embodiment, in addition to the configuration of the first embodiment, a short circuit constituted by a p-type transistor P16 and a buffer B11 is provided in the first circuit 10, and a short circuit constituted by a p-type transistor P26 and a buffer B21 is provided in the second circuit 20.

### First Circuit

The p-type transistor P16 (corresponding to the eleventh p-type transistor) is provided in parallel with the resistor R11. In other words, the resistor R11 and the p-type transistor P16 are provided in parallel between the node n1 and the node n2.

The buffer B11 (corresponding to the first buffer) is provided between the output node out and the gate of the p-type transistor P16. The power supply terminal of the buffer B11 is connected to the third power supply VDDIO and the ground terminal thereof is connected to the first power supply VDD.

### Second Circuit

The p-type transistor P26 (corresponding to the twelfth p-type transistor) is provided in parallel with the resistor R21. In other words, the resistor R21 and the p-type transistor P26 are provided in parallel between the node n1b and the node n2b.

The buffer B21 (corresponding to the second buffer) is provided between the inverted output node outb and the gate of the p-type transistor P26. The power supply terminal of the buffer B21 is connected to the third power supply VDDIO and the ground terminal thereof is connected to the first power supply VDD.

### Operation of Level Shifting Circuit

Next, the operation of the level shifting circuit 1 according to this embodiment will be described with reference to FIG. 2. The features of the voltage waveforms according to this embodiment are shown by the broken lines at time t1 to time t4 in FIG. 2. Description here will be made centering on differences from the description of the operation of the level shifting circuit 1 according to the first embodiment.

### Operation Example (2-1)

The operation at the time when ‘L’ is input as the input signal IN is similar to Operation Example (1-1) in the first embodiment.

At this time, since the output signal OUT is ‘L’ (voltage VDD) and the voltages of the nodes n2 and n1 are VSS, the p-type transistor P16 is OFF. Also, since the voltages at the inverted output node outb and the nodes n2b and n1b are VDDIO, the p-type transistor P26 does not act.

-Operation Example (2-2)-

The operation at the time when ‘H’ is input as the input signal IN is similar to Operation Example (1-2) in the first embodiment.

At this time, since the output signal OUT is ‘H’ (voltage VDDIO) and the voltages of the nodes n2 and n1 are VDDIO, the p-type transistor P16 does not act. Also, since the voltage of the inverted output node outb is VDD and the voltages of the nodes n2b and n1b are VSS, the p-type transistor P26 is OFF.

### Operation Example (2-3)

The operation at the time when the input signal IN changes from ‘L’ to ‘H’ will be described. Description here will be made centering on differences from the first embodiment.

In the first circuit 10, the voltage of the output signal OUT is input into the gate of the p-type transistor P16 lagging by a delay time of the buffer B11. That is, ‘L’ (voltage VDD) is input for a predetermined time period after the start of rising of the output signal OUT (see time t2), and this turns ON the p-type transistor P16, short-circuiting both ends of the resistor R11. This makes the rise at the node n1 faster than in Operation Example (1-3) in the first embodiment as indicated by the broken line in FIG. 2. With this, since, having no potential difference occurring between the node n1 and the node n2, the p-type transistor P11 turns OFF, the rise at the node n2 is sped up. As a result, the turning-OFF of the p-type transistor P13 is hastened, and the rise of the output signal OUT is sped up.

In the second circuit 20, the voltage of the inverted output node outb is input into the gate of the p-type transistor P26 lagging by a delay time of the buffer B21. That is, ‘H’ (voltage VDDIO) is input for a predetermined time period after the start of falling of the voltage of the inverted output node outb, and this turns OFF the p-type transistor P26, not short-circuiting both ends of the resistor R21. Therefore, at the fall of the inverted output node outb, the effect in the first embodiment is retained. Note that, since the rise of the output signal OUT is sped up as described above, the turning-OFF of the p-type transistor P22 is hastened. Therefore, in comparison with the first embodiment, the fall of the inverted output node outb and the nodes n2b and n1b is sped up (see the broken lines in FIG. 2).

### Operation Example (2-4)

The operation at the time when the input signal IN changes from ‘H’ to ‘L’ will be described.

As in Operation Example (1-4) described above, in this operation example, the first circuit 10 and the second circuit 20 perform reciprocal operations in comparison with Operation Example (2-3).

### Effects of Second Embodiment

As described above, according to this embodiment, the first circuit 10 is configured so that, at the rise of the output signal OUT and the node n1, the p-type transistor P16 turns ON to short-circuit both ends of the resistor R11. With this configuration, since no voltage drop occurs at the resistor R11, occurrence of a time period when the third power supply VDDIO and the first power supply VDD are brought into conduction is avoided, and therefore the rising speed of the output signal OUT can be increased. Also, at the fall of the output signal OUT, the p-type transistor P16 turns OFF, not short-circuiting both ends of the resistor R11. This retains the effect in the first embodiment by the resistor R11. The second circuit 20 acts similarly by its reciprocal operation.

### Third Embodiment

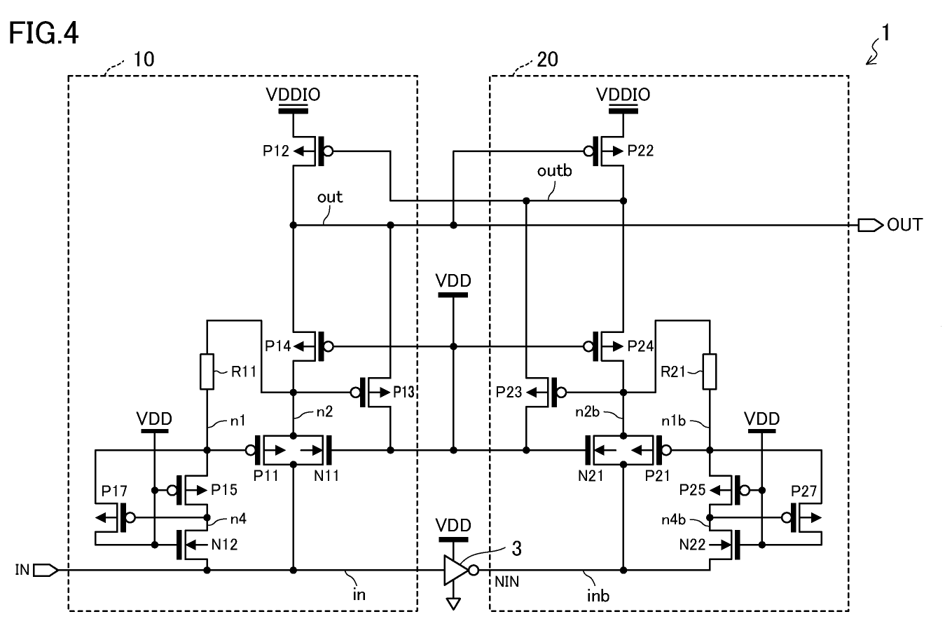

FIG. 4 shows an example of the circuit diagram of a level shifting circuit 1 according to the third embodiment. In FIG. 4, components corresponding to those in FIG. 1 are denoted by the same reference characters. The following description will be made centering on differences from the first embodiment.

The level shifting circuit 1 of this embodiment is configured to further speed up the fall of the output signal OUT from ‘H’ to ‘L’ in comparison with the first embodiment.

In the configuration of the first embodiment, at the fall of the output signal OUT, since the nodes n1 and n2 also fall, the Vgs of the p-type transistors P14 and P15 decreases, causing the source-drain current to gradually decrease. This reduces the discharge current from the output signal OUT to the input node in (voltage VSS) via the p-type transistors P14 and P15. Since this makes the fall at the nodes n1 and n2 mild, the turning-ON of the p-type transistor P11 may not be hastened. In such a case, the mild fall at the node n2 may continue, the p-type transistor P13 may not turn ON, and the fall of the output signal OUT may not be hastened. As a result, the high-speed operation may be affected.

In view of the above, in this embodiment, from the standpoint of speeding up the fall of the output signal OUT, a p-type transistor P17 is additionally provided in the first circuit 10 and a p-type transistor P27 is additionally provided in the second circuit 20, in addition to the configuration of the first embodiment.

### First Circuit

The p-type transistor P17 (corresponding to the thirteenth p-type transistor) is provided between the node n1 and the first power supply VDD, and has a gate connected to the node n4.

### Second Circuit

The p-type transistor P27 (corresponding to the fourteenth p-type transistor) is provided between the node n1b and the first power supply VDD, and has a gate connected to the node n4b.

### Operation of Level Shifting Circuit

Next, the operation of the level shifting circuit 1 according to this embodiment will be described with reference to FIG. 2. The features of the voltage waveforms according to this embodiment are shown by the broken lines at time t5 to time t8 in FIG. 2. Description here will be made centering on differences from the description of the operation of the level shifting circuit 1 according to the first embodiment.

### Operation Example (3-1)

The operation at the time when ‘L’ is input as the input signal IN is similar to Operation Example (1-1) in the first embodiment.

At this time, since the voltage of the node n4 is VSS, the p-type transistor P17 is ON. Also, since the voltage of the node n4b is VDDIO, the p-type transistor P27 is OFF.

### Operation Example (3-2)

The operation at the time when ‘H’ is input as the input signal IN is similar to Operation Example (1-2) in the first embodiment.

Note that, since the voltage of the node n4 is VDDIO, the p-type transistor P17 is OFF. Also, since the voltage of the node n4b is VSS, the p-type transistor P27 is ON.

### Operation Example (3-3)

The operation at the time when the input signal IN changes from ‘H’ to ‘L’ will be described. Description here will be made centering on differences from the first embodiment.

At time t5, in the first circuit 10, the voltage of the node n4 starts to fall. When the Vgs of the p-type transistor P17 exceeds the threshold, the p-type transistor P17 turns ON. With this, as indicated by the broken lines at t5 to t7 in FIG. 2, since the voltage of the node n1 falls faster than in the first embodiment, the turning-ON of the p-type transistor P11 is hastened, and also the falling speed of the voltage of the node n2 increases. This turns ON the p-type transistor P13 faster than in the first embodiment, increasing the falling speed of the output signal OUT.

At this time, in the second circuit 20, the node n4b starts to rise, and when the Vgs of the p-type transistor P27 becomes less than the threshold, the p-type transistor P27 turns OFF. Therefore, in the second circuit 20, the p-type transistor P27 is kept from hindering the rise of the inverted output node outb and the nodes n1b, n2b, and n4b.

Note that, since the falling speed of the output signal OUT increases, the turning-ON of the p-type transistor P22 is hastened, thereby increasing the rising speeds of the voltages at the inverted output node outb and the nodes n1b, n2b, and n4b in comparison with the first embodiment (see the broken lines at time t6 to time t8).

### Operation Example (3-4)

As described above, the first circuit 10 and the second circuit 20 are symmetric to each other in configuration. Also, when the input signal IN changes from ‘L’ to ‘H’, the inverted input signal NIN changes from ‘H’ to ‘L’. Therefore, in this operation example, the first circuit 10 and the second circuit 20 perform reciprocal operations in comparison with Operation Example (3-3).

### Effects of Third Embodiment

As described above, according to this embodiment, the p-type transistor P17 is configured to turn ON at the fall of the output signal OUT to increase the falling speeds at the nodes n1 and n2, thereby hastening the turning-ON of the p-type transistor P11. This turns ON the p-type transistor P13 faster than in the first embodiment, thereby increasing the falling speed of the output signal OUT.

Also, since the p-type transistor P17 turns OFF at the rise of the output signal OUT, the effect in the first embodiment is retained. The second circuit 20 acts similarly by its reciprocal operation.

### Fourth Embodiment

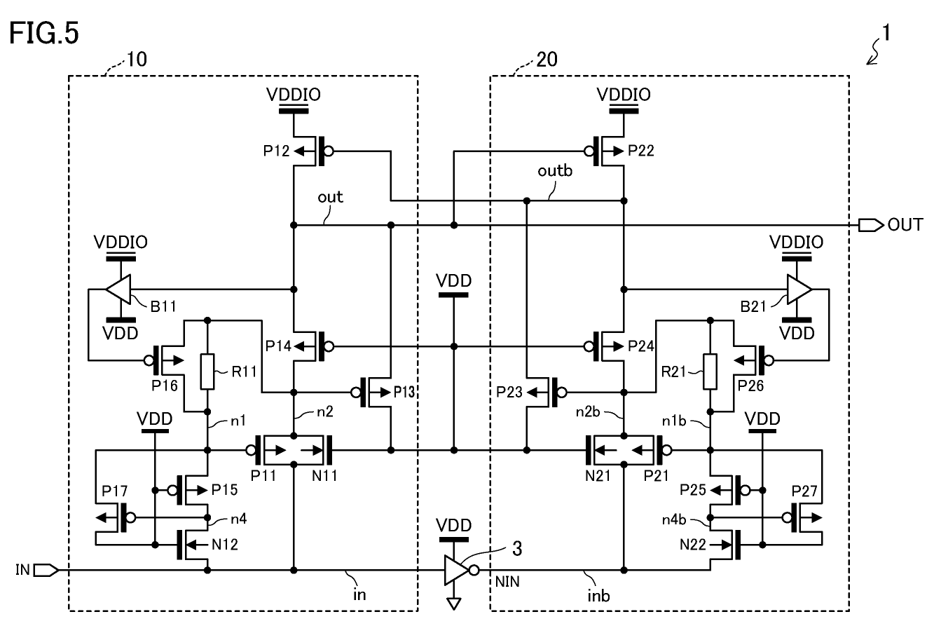

FIG. 5 shows an example of the circuit diagram of a level shifting circuit 1 according to the fourth embodiment. As shown in FIG. 5, this embodiment has a configuration in which both the circuits additionally provided in the second embodiment and the third embodiment are added together to the configuration of the first embodiment. In FIG. 5, components corresponding to those in FIGS. 1, 3, and 4 are denoted by the same reference characters.

Having such a configuration, the rise and fall of an output signal OUT are sped up, whereby further speedup is achieved.

As shown in FIG. 5, the level shifting circuit 1 includes a first circuit 10, a second circuit 20, and an inverter 3 that inverts an input signal IN to generate an inverted input signal NIN.

### First Circuit

The first circuit includes n-type transistors N11 and N12, p-type transistors P11 to P17, a resistor R11, and a buffer B11.

The n-type transistor N11 (corresponding to the first n-type transistor) is provided between an input node in and a node n2 (corresponding to the first node), and has a gate connected to the first power supply VDD. The p-type transistor P11 (corresponding to the first p-type transistor) is provided between the input node in and the node n2, and has a gate connected to a node n1 (corresponding to the second node). The p-type transistor P14 (corresponding to the second p-type transistor) is provided between the node n2 and an output node out, and has a gate connected to the first power supply VDD. The p-type transistor P12 (corresponding to the third p-type transistor) is provided between the third power supply VDDIO and the output node out, and has a gate connected to an inverted output node outb. The p-type transistor P13 (corresponding to the fourth p-type transistor) is provided between the first power supply VDD and the output node out, and has a gate connected to the node n2. The n-type transistor N12 (corresponding to the second n-type transistor) is provided between the input node in and a node n4 (corresponding to the third node), and has a gate connected to the first power supply VDD. The p-type transistor P15 (corresponding to the fifth p-type transistor) is provided between the node n4 and the node n1, and has a gate connected to the first power supply VDD. The resistor R11 (corresponding to the first resistor) is provided between the node n1 and the node n2. The p-type transistor P16 (corresponding to the sixth p-type transistor) is provided in parallel with the resistor R11, between the node n1 and the node n2 in this case. The buffer B11 (corresponding to the first buffer) is provided between the output node out and the gate of the p-type transistor P16. The p-type transistor P17 (corresponding to the seventh p-type transistor) is provided between the node n1 and the first power supply VDD, and has a gate connected to the node n4.

### Second Circuit

The second circuit includes n-type transistors N21 and N22, p-type transistors P21 to P27, a resistor R21, and a buffer B21.

The n-type transistor N21 (corresponding to the third n-type transistor) is provided between an inverted input node inb and a node n2b (corresponding to the fourth node), and has a gate connected to the first power supply VDD. The p-type transistor P21 (corresponding to the eighth p-type transistor) is provided between the inverted input node inb and the node n2b, and has a gate connected to a node n1b (corresponding to the fifth node). The p-type transistor P24 (corresponding to the ninth p-type transistor) is provided between the node n2b and the inverted output node outb, and has a gate connected to the first power supply VDD. The p-type transistor P22 (corresponding to the tenth p-type transistor) is provided between the third power supply VDDIO and the inverted output node outb, and has a gate connected to the output node out. The p-type transistor P23 (corresponding to the eleventh p-type transistor) is provided between the first power supply VDD and the inverted output node outb, and has a gate connected to the node n2b. The n-type transistor N22 (corresponding to the fourth n-type transistor) is provided between the inverted input node inb and a node n4b (corresponding to the sixth node), and has a gate connected to the first power supply VDD. The p-type transistor P25 (corresponding to the twelfth p-type transistor) is provided between the node n4b and the node n1b, and has a gate connected to the first power supply VDD. The resistor R21 (corresponding to the second resistor) is provided between the node n1b and the node n2b. The p-type transistor P26 (corresponding to the thirteenth p-type transistor) is provided in parallel with the resistor R21, between the node n1b and the node n2b in this case. The buffer B21 (corresponding to the second buffer) is provided between the inverted output node outb and the gate of the p-type transistor P26. The p-type transistor P27 (corresponding to the fourteenth p-type transistor) is provided between the node n1b and the first power supply VDD, and has a gate connected to the node n4b.

### Operation of Level Shifting Circuit

Next, the operation of the level shifting circuit 1 according to this embodiment will be described with reference to FIG. 2. In this embodiment, combined effects of the second embodiment and the third embodiment are obtained. The features of the voltage waveforms according to this embodiment are shown by the broken lines at time t1 to time t8 in FIG. 2.

### Operation Example (4-1)

The operation at the time when ‘L’ is input as the input signal IN is similar to Operation Example (1-1) in the first embodiment.

As described in Operation Example (2-1), the p-type transistor P16 is OFF, and the p-type transistor P26 does not act. Also, as described in Operation Example (3-1), the p-type transistor P17 is ON, and the p-type transistor P27 is OFF.

### Operation Example (4-2)

The operation at the time when ‘H’ is input as the input signal IN is similar to Operation Example (1-2) in the first embodiment.

As described in Operation Example (2-2), the p-type transistor P16 does not act, and the p-type transistor P26 is OFF. Also, as described in Operation Example (3-2), the p-type transistor P17 is OFF, and the p-type transistor P27 is ON.

### Operation Example (4-3)

The operation at the time when the input signal IN changes from ‘L’ to ‘H’ is similar to Operation Example (2-3) in the second embodiment.

### Operation Example (4-4)

The operation at the time when the input signal IN changes from ‘H’ to ‘L’ is similar to Operation Example (3-3) in the third embodiment.

### Alteration

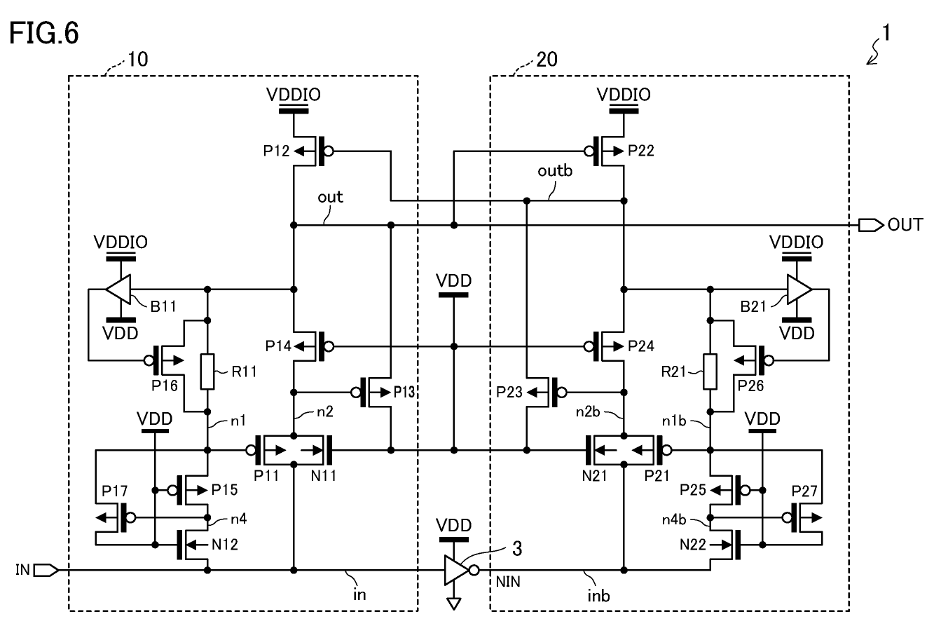

FIG. 6 shows an alteration of the level shifting circuit 1 according to the fourth embodiment. In FIG. 6, components corresponding to those in FIG. 5 are denoted by the same reference characters. The following description will be made centering on differences from the fourth embodiment.

In this alteration, in comparison with the fourth embodiment, one end of the resistor R11 is connected to the output node out, not to the node n2. Also, one end of the resistor R21 is connected to the inverted output node outb, not to the node n2b. The other configuration is the same as that in the fourth embodiment.

Note that, in the first to third embodiments, also, one end of the resistor R11 may be connected to the output node out, not to the node n2, and one end of the resistor R21 may be connected to the inverted output node outb, not to the node n2b, as in FIG. 6. In these cases, also, effects equivalent to those in the respective embodiments are obtained.

### Operation of Level Shifting Circuit

Next, the operation of the level shifting circuit 1 in FIG. 6 will be described.

### Operation Example (4-5)

The operation at the time when the input signal IN changes from ‘L’ to ‘H’ will be described.

First, the operation in the case of applying this alteration to the second and fourth embodiments will be described. In this alteration, in the first circuit 10, the p-type transistor P16 is provided in parallel with the resistor R11. Therefore, when the p-type transistor P16 is turned ON at the same timing as in these embodiments, both ends of the resistor R11 are short-circuited. Characteristics equivalent to those in the respective embodiments are therefore obtained.

Next, the operation in the case of applying this alteration to the first and third embodiments will be described. Note here that, in this alteration, the voltage ‘L’ is VDD at the node n1 while it is VSS at the node n2. Therefore, this alteration has a feature that it is easy to design so as to keep the Vgs of the p-type transistor P11 from exceeding the threshold at the time of rise of the nodes n1 and n2. With the p-type transistor P11 being OFF, the rise of the output signal OUT can be made faster than in the first and third embodiments.

### Operation Example (4-6)

The operation at the time when the input signal IN changes from ‘H’ to ‘L’ will be described. Here, the operation in the case of applying this alteration to the first to fourth embodiments will be described.

In the configuration of this alteration, at the node n1, there is a voltage drop by an amount caused by the passing through the resistor R11 from the output node out. At the node n2, there is a voltage drop due to the ON resistance of the p-type transistor P14 that is on the route from the output node out. Therefore, the resistance value of the resistor R11 is designed considering the potential difference between the node n2 and the node n1 (n1 < n2). Specifically, characteristics equivalent to those in the first to fourth embodiments are obtained by designing the resistance value of the resistor R11 so that the Vgs of the p-type transistor P11 exceed the threshold.

### Fifth Embodiment

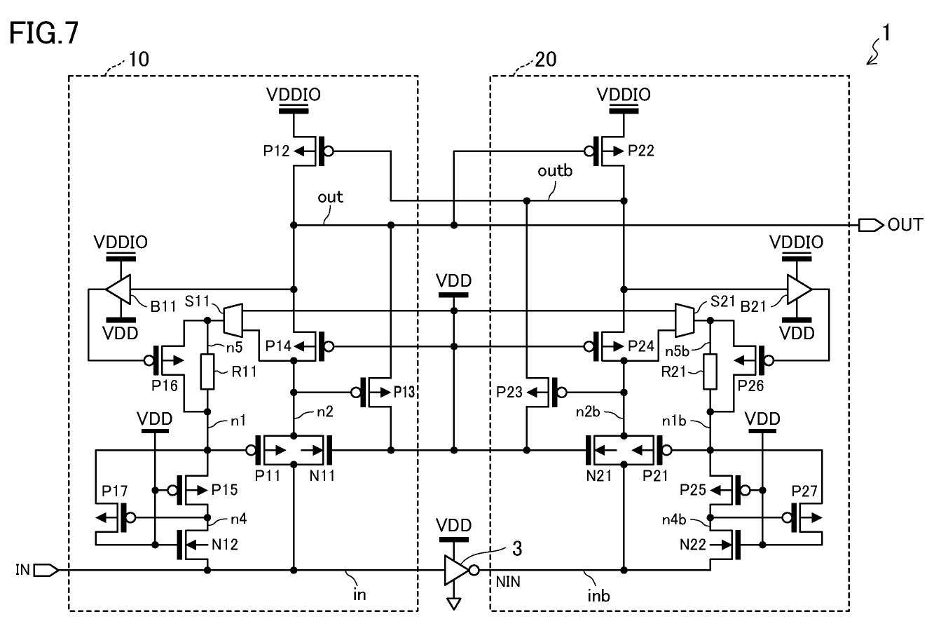

FIG. 7 shows an example of the circuit diagram of a level shifting circuit 1 according to the fifth embodiment.

In FIG. 7, components corresponding to those in FIG. 5 (fourth embodiment) are denoted by the same reference characters. The following description will be made centering on differences from the fourth embodiment.

The level shifting circuit 1 of this embodiment is configured to keep the circuit area from increasing. Specifically, in the level shifting circuit 1 of this embodiment, a voltage comparison circuit S11 is provided in the first circuit 10 and a voltage comparison circuit S21 is provided in the second circuit 20, in addition to the configuration of the fourth embodiment.

### First Circuit

The voltage comparison circuit S11 is a 2-input 1-output comparison circuit interposed between the resistor R11 and the output node out. Specifically, the first voltage VDD is connected to one of the input terminals of the voltage comparison circuit S11, and the node n2 is connected to the other input terminal thereof. That is, the other input terminal of the voltage comparison circuit S11 is connected to the output node out via the node n2 and the p-type transistor P14. The output terminal of the voltage comparison circuit S11 is connected to a node n5 to which the resistor R11 and the p-type transistor P16 are connected. In other words, the resistor R11 and the p-type transistor P16 are provided in parallel between the node n1 and the node n5.

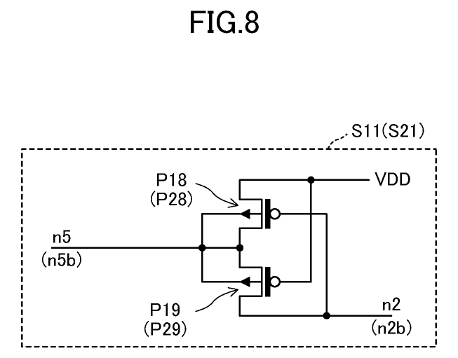

FIG. 8 shows a configuration example of the voltage comparison circuit S11. In the example of FIG. 8, the voltage comparison circuit S11 includes p-type transistors P18 and P19. The p-type transistor P18 is provided between the first power supply VDD and the node n5, and has a gate connected to the node n2. The p-type transistor P19 is provided between the node n5 and the node n2, and has a gate connected to the first power supply VDD. When the voltage of the node n2 is VDD or less, the p-type transistor P18 turns ON allowing conduction between the first power supply VDD and the node n5. On the other hand, when the voltage of the node n2 exceeds VDD, the p-type transistor P19 turns ON allowing conduction between the node n5 and the node n2. Note that, in FIG. 8, the configuration example of the voltage comparison circuit S21 is shown in parentheses. The configuration of the voltage comparison circuits S11 and S21 is not limited to that in FIG. 8, but a voltage comparison circuit of any other configuration having a similar function may be used.

### Second Circuit

The voltage comparison circuit S21 is a 2-input 1-output comparison circuit and interposed between the resistor R21 and the inverted output node outb. Specifically, the first voltage VDD is connected to one of the input terminals of the voltage comparison circuit S21, and the node n2b is connected to the other input terminal thereof. That is, the other input terminal of the voltage comparison circuit S21 is connected to the inverted output node outb via the node n2b and the p-type transistor P24. The output terminal of the voltage comparison circuit S21 is connected to a node n5b to which the resistor R21 and the p-type transistor P26 are connected. In other words, in this embodiment, the resistor R21 and the p-type transistor P26 are provided in parallel between the node n1b and the node n5b.

### Operation of Level Shifting Circuit

Next, the operation of the level shifting circuit 1 according to this embodiment will be described with reference to FIG. 2. In this embodiment, effects equivalent to those in the fourth embodiment are obtained. That is, the features of the voltage waveforms according to this embodiment are shown by the broken lines at time t1 to time t8 in FIG. 2.

### Operation Example (5-1)

The operation at the time when ‘L’ is input as the input signal IN is similar to Operation Example (4-1) in the fourth embodiment.

### Operation Example (5-2)

The operation at the time when ‘H’ is input as the input signal IN is similar to Operation Example (4-2) in the fourth embodiment.

### Operation Example (5-3)

The operation at the time when the input signal IN changes from ‘L’ to ‘H’ will be described. The description here will be made centering on differences from the fourth embodiment.

In the first circuit 10, when the voltage of the node n2 is VDD or less, the p-type transistor P18 turns ON allowing conduction between the first power supply VDD and the node n5. When the voltage of the node n2 rises exceeding VDD, the node n5 and the node n2 are brought into conduction. At this time, since the p-type transistor P16 short-circuits both ends of the resistor R11, the operation in the fourth embodiment is retained.

In the second circuit 20, during the time when the voltage of the node n2b is higher than VDD, the node n5b and the node n2b are brought into conduction. At this time, the p-type transistor P21 turns ON with its Vgs exceeding the threshold due to a voltage drop caused by the ON resistance of the p-type transistor P29 and the resistor R21. Thus, the operation in the fourth embodiment is retained.

### Operation Example (5-4)

As for the operation at the time when the input signal IN changes from ‘H’ to ‘L’, the first circuit 10 and the second circuit 20 perform reciprocal operations in comparison with Operation Example (5-3).

### Effects of Fifth Embodiment

As described above, according to this embodiment, in the first circuit 10, since design can be made so that the total resistance value of the resistor R11 and the ON resistance of the p-type transistor P19 will be of the same level as that of the resistor R11 in the fourth embodiment, the resistance value of the resistor R11 can be reduced. It is therefore possible to obtain characteristics equivalent to those in the fourth embodiment while reducing the area of the resistor R11 and the area occupied by the level shifting circuit 1. This also applies to the second circuit 20.

Moreover, in this embodiment, when the input signal IN is ‘L’, the voltage of the node n1 is VDD while the voltage of the node n2 is VSS. Therefore, this embodiment has a feature that it is easy to design so that the Vgs of the p-type transistor P11 will not exceed the threshold at the rise of the nodes n1 and n2.

### Alteration

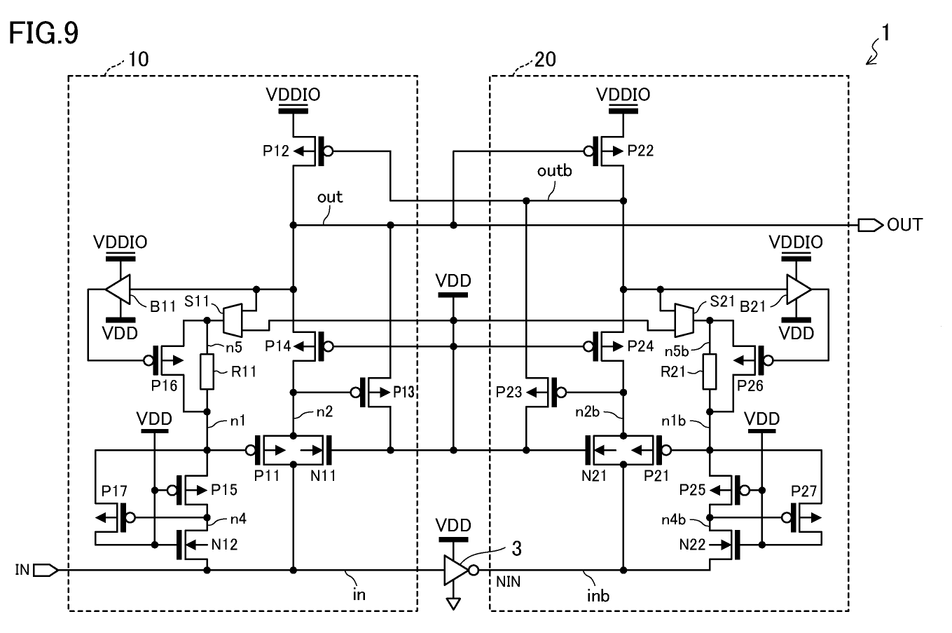

FIG. 9 shows an alteration of the level shifting circuit 1 according to the fifth embodiment. In FIG. 9, components corresponding to those in FIG. 7 are denoted by the same reference characters. The following description will be made centering on differences from the fifth embodiment.

In this alteration, in comparison with the fifth embodiment, one input of the voltage comparison circuit S11 is connected to the output node out, not to the node n2. Also, one input of the voltage comparison circuit S21 is connected to the inverted output node outb, not to the node n2b. The other configuration is the same as that in the fifth embodiment.

### Operation of Level Shifting Circuit

Next, the operation of the level shifting circuit 1 in FIG. 9 will be described.

### Operation Example (5-5)

The operation at the time when the input signal IN changes from ‘L’ to ‘H’ will be described.

In the first circuit 10, the p-type transistor P16 is provided in parallel with the resistor R11. The p-type transistor P16 is turned ON at the same timing as in the fifth embodiment, and then the resistor R11 is short-circuited. Therefore, characteristics equivalent to those in the fifth embodiment are obtained.

### Operation Example (5-6)

The operation at the time when the input signal IN changes from ‘H’ to ‘L’ will be described.

In this alteration, the resistor R11 and the p-type transistor P14 are in parallel with each other. Therefore, at the design of the resistance value of the resistor R11, the ON resistance of the p-type transistor P14 may be added to the resistance value to ensure that the Vgs of the p-type transistor P11 exceeds the threshold. With this, characteristics equivalent to those in the fifth embodiment are obtained.

Note that the technique in the present disclosure is applicable, not only to the configurations described in the above embodiments, but also to embodiments appropriately subjected to changes, replacements, additions, and omissions from the above embodiments. Also, the components described in the above embodiments can be combined to provide a new embodiment.

The level shifting circuit according to the present disclosure is highly useful because it responds to reduction in operating voltages and/or speedup of circuit operation.

1. A level shifting circuit, comprising:
an input node receiving an input signal that makes a transition between a first power supply and a second power supply lower in potential than the first power supply;
a first n-type transistor provided between the input node and an output node and having a gate connected to the first power supply;
a first p-type transistor provided in parallel with the first n-type transistor between the input node and the output node and having a gate connected to a first node;
a first resistor provided between the first node and the output node;
a second p-type transistor provided between a third power supply higher in potential than the first power supply and the output node and having a gate connected to an inverted output node;
a third p-type transistor provided between the first power supply and the output node and having a gate connected to the output node via a second node;
an inverted input node receiving an inverted input signal inverted from the input signal;
a second n-type transistor provided between the inverted input node and the inverted output node and having a gate connected to the first power supply;
a fourth p-type transistor provided in parallel with the second n-type transistor between the inverted input node and the inverted output node and having a gate connected to a third node;
a second resistor provided between the third node and the inverted output node;
a fifth p-type transistor provided between the third power supply and the inverted output node and having a gate connected to the output node; and
a sixth p-type transistor provided between the first power supply and the inverted output node and having a gate connected to the inverted output node via a fourth node.

2. The level shifting circuit of claim 1, further comprising:
a seventh p-type transistor provided between the output node and the second node and having a gate connected to the first power supply;
a third n-type transistor provided between the input node and a fifth node and having a gate connected to the first power supply;
an eighth p-type transistor provided between the fifth node and the first node and having a gate connected to the first power supply;
a ninth p-type transistor provided between the inverted output node and the fourth node and having a gate connected to the first power supply;
a fourth n-type transistor provided between the inverted input node and a sixth node and having a gate connected to the first power supply; and
a tenth p-type transistor provided between the sixth node and the third node and having a gate connected to the first power supply.

3. The level shifting circuit of claim 1, further comprising:
an eleventh p-type transistor provided in parallel with the first resistor;
a first buffer provided between the output node and a gate of the eleventh p-type transistor;
a twelfth p-type transistor provided in parallel with the second resistor; and
a second buffer provided between the inverted output node and a gate of the twelfth p-type transistor.

4. The level shifting circuit of claim 2, further comprising:
a thirteenth p-type transistor provided between the first node and the first power supply and having a gate connected to the fifth node; and
a fourteenth p-type transistor provided between the third node and the first power supply and having a gate connected to the sixth node;

5. The level shifting circuit of claim 4, further comprising:
an eleventh p-type transistor provided in parallel with the first resistor;
a first buffer provided between the output node and a gate of the eleventh p-type transistor;
a twelfth p-type transistor provided in parallel with the second resistor; and
a second buffer provided between the inverted output node and a gate of the twelfth p-type transistor.

6. The level shifting circuit of claim 1, further comprising:
a first voltage comparison circuit interposed between the first resistor and the output node;
a second voltage comparison circuit interposed between the second resistor and the inverted output node;
a seventh p-type transistor provided between the output node and the second node and having a gate connected to the first power supply; and
a ninth p-type transistor provided between the inverted output node and the fourth node and having a gate connected to the first power supply,
wherein
in the first voltage comparison circuit, the first power supply is connected to one of its inputs, the second node or the output node is connected to the other input, and the first resistor is connected to its output, and
in the second voltage comparison circuit, the first power supply is connected to one of its inputs, the fourth node or the inverted output node is connected to the other input, and the second resistor is connected to its output.

7. The level shifting circuit of claim 4, further comprising:
a first voltage comparison circuit interposed between the first resistor and the output node; and
a second voltage comparison circuit interposed between the second resistor and the inverted output node;
wherein
in the first voltage comparison circuit, the first power supply is connected to one of its inputs, the second node or the output node is connected to the other input, and the first resistor is connected to its output, and
in the second voltage comparison circuit, the first power supply is connected to one of its inputs, the fourth node or the inverted output node is connected to the other input, and the second resistor is connected to its output.

8. A level shifting circuit, comprising:
an input node receiving an input signal that makes a transition between a first power supply and a second power supply lower in potential than the first power supply;
a first n-type transistor provided between the input node and a first node and having a gate connected to the first power supply;
a first p-type transistor provided between the input node and the first node and having a gate connected to a second node;
a second p-type transistor provided between the first node and an output node and having a gate connected to the first power supply;
a third p-type transistor provided between a third power supply higher in potential than the first power supply and the output node and having a gate connected to an inverted output node;
a fourth p-type transistor provided between the first power supply and the output node and having a gate connected to the first node;
a second n-type transistor provided between the input node and a third node and having a gate connected to the first power supply;
a fifth p-type transistor provided between the third node and the second node and having a gate connected to the first power supply;
a first resistor provided between the second node and the first node or the output node;
a sixth p-type transistor provided in parallel with the first resistor;
a first buffer provided between the output node and a gate of the sixth p-type transistor;
a seventh p-type transistor provided between the second node and the first power supply and having a gate connected to the third node;
an inverted input node receiving an inverted input signal inverted from the input signal;
a third n-type transistor provided between the inverted input node and a fourth node and having a gate connected to the first power supply;
an eighth p-type transistor provided between the inverted input node and the fourth node and having a gate connected to a fifth node;
a ninth p-type transistor provided between the fourth node and the inverted output node and having a gate connected to the first power supply;
a tenth p-type transistor provided between the third power supply and the inverted output node and having a gate connected to the output node;
an eleventh p-type transistor provided between the first power supply and the inverted output node and having a gate connected to the fourth node;
a fourth n-type transistor provided between the inverted input node and a sixth node and having a gate connected to the first power supply;
a twelfth p-type transistor provided between the sixth node and the fifth node and having a gate connected to the first power supply;
a second resistor provided between the fifth node and the fourth node or the inverted output node;
a thirteenth p-type transistor provided in parallel with the second resistor;
a second buffer provided between the inverted output node and a gate of the thirteenth p-type transistor; and
a fourteenth p-type transistor provided between the fifth node and the first power supply and having a gate connected to the sixth node.

9. The level shifting circuit of claim 8, further comprising:
a first voltage comparison circuit interposed between the first resistor and the output node; and
a second voltage comparison circuit interposed between the second resistor and the inverted output node;
wherein
in the first voltage comparison circuit, the first power supply is connected to one of its inputs, the second node or the output node is connected to the other input, and the first resistor is connected to its output, and
in the second voltage comparison circuit, the first power supply is connected to one of its inputs, the fourth node or the inverted output node is connected to the other input, and the second resistor is connected to its output.
